(19) United States
(12) Patent Application Publication
(10) Pub. No.: US 2012/0205703 A1
(43) Pub. Date: Aug. 16, 2012

(54) Light-Emitting Diode Package Device and Method for Making the Same

(75) Inventor: Po-Jen SU, Tainan City (TW)

(73) Assignee: GENESIS PHOTONICS INC., Tainan City (TW)

(21) Appl. No.: 13/371,817

(22) Filed: Feb. 13, 2012

(30) Foreign Application Priority Data
Feb. 15, 2011 (TW) 100104945

(51) Int. Cl. H01L 33/44; H01L 33/52

(52) U.S. Cl. 257/98; 438/27; 257/E33.059; 257/E33.061

(57) ABSTRACT

A light-emitting diode package device includes: a base unit defining a packaging space; a light-emitting diode die that is disposed inside the packaging space to electrically connect to the base unit and that is capable of emitting light; and an encapsulant that is filled in the packaging space to encapsulate the light-emitting diode die and that includes an upper surface to be exposed to external environment, and a plurality of microstructures formed on the upper surface.

### CROSS-REFERENCE TO RELATED APPLICATION

This application claims priority of Taiwanese Patent application no. 100104945, filed on Feb. 15, 2011.

### BACKGROUND OF THE INVENTION

1. Field of the Invention

The present invention relates to a package device and a method for making the same, more particularly to a light-emitting diode package device and a method for making the same.

2. Description of the Related Art

Referring to FIG. 1, a conventional light-emitting diode package device 11 includes a base unit 111, a light-emitting diode die 112, and an encapsulant 113.

The base unit 111 has a lead frame 116 and a cup member 115 and defines a packaging space 117. The cup member 115 is formed upwardly from the lead frame 116. The lead frame 116 is made of a metal material so as to electrically connect to an external circuit. A part of the lead frame 116 is exposed to the packaging space 117. The packaging space 117 has an opening 118 that is away from the part of the lead frame 116 exposed to the packaging space 117.

The light-emitting diode die 112 is disposed inside the packaging space 117 to electrically connect to the lead frame 116 that is exposed to the cup member 115, and is capable of emitting light. In FIG. 1, the lead frame 116 and the light-emitting diode die 112 are electrically connected together using gold wires 114.

The encapsulant 113 is filled in the packaging space 117 to encapsulate the light-emitting diode die 112 and close the opening 118 of the packaging space 117 so that the light-emitting diode die 112 is isolated from the external environment and is protected from moisture and gas in the external environment which may cause early aging of the light-emitting diode die 112.

When electricity is supplied from the external circuit to the base unit 111, electricity is transmitted to the light-emitting diode die 112 through the lead frame 116 of the base unit 111, and the light-emitting diode die 112 is then energized to emit light with predetermined wavelength. The emitted light passes through the encapsulant 113 and then emits outwardly.

Referring to FIG. 2, a method for making the conventional light-emitting diode package device 11 includes a step 121 of disposing the light-emitting diode die 112 inside the packaging space 117 to electrically connect to the lead frame 116 of the base unit 111, and a step 122 of forming the encapsulant 113 by filling an encapsulating material in the packaging space 117 to encapsulate the light-emitting diode die 112.

In the conventional light-emitting diode package device 11, since the top surface of the conventional light-emitting diode die 112 and the top surface of the encapsulant 113 are both planar surfaces, the light from the light-emitting diode die 112 is likely to pass directly through the encapsulant 113 and emits orthogonally from the surface of the encapsulant 113 to the external environment. The emitting angle of the light from the light-emitting diode die 112 is thus almost unchanged. Therefore, the unadjusted and unmodified light path causes the outwardly emitting light to be non-uniform.

### SUMMARY OF THE INVENTION

The object of the present invention is to provide a light-emitting diode package device that can enhance light uniformity and a method for making the light-emitting diode package device.

According to one aspect, a light-emitting diode package device of the present invention comprises: a base unit defining a packaging space; a light-emitting diode die that is disposed inside the packaging space to electrically connect to the base unit and that is capable of emitting light; and an encapsulant that is filled in the packaging space to encapsulate the light-emitting diode die and that includes an upper surface to be exposed to external environment, and a plurality of microstructures formed on the upper surface.

According to another aspect, a method for making a light-emitting diode package device comprises: (a) disposing a light-emitting diode die inside a packaging space defined by a base unit such that the light-emitting diode die is electrically connected to the base unit; (b) forming an encapsulant by filling an encapsulating material in the packaging space to encapsulate the light-emitting diode die; and (c) forming a plurality of microstructures on an upper surface of the encapsulant that is to be exposed to external environment, the microstructures being spaced apart from one another by a distance smaller than 20 microns, each of the microstructures having an end surface spaced apart from the upper surface of the encapsulant, a distance between the end surface of each of the microstructures and the upper surface of the encapsulant being greater than a wavelength of the light emitted from the light-emitting diode die, and being smaller than 2.0 microns.

### BRIEF DESCRIPTION OF THE DRAWINGS

Other features and advantages of the present invention will become apparent in the following detailed description of the preferred embodiments with reference to the accompanying drawings, of which:

FIG. 1 is a cross sectional schematic view of a conventional light-emitting diode package device;

FIG. 2 is a flow chart illustrating a method for making the light-emitting diode package device shown in FIG. 1;

FIG. 3 is a cross sectional schematic view of the first preferred embodiment of a light-emitting diode package device according to the present invention;

FIG. 4 is a flow chart illustrating the preferred embodiment of a method for making the first preferred embodiment of the light-emitting diode package device;

FIG. 5 is a cross sectional schematic view of the second preferred embodiment of a light-emitting diode package device according to the present invention;

FIG. 6 is a cross sectional schematic view of the third preferred embodiment of a light-emitting diode package device according to the present invention; and

FIG. 7 is a cross sectional schematic view of the fourth preferred embodiment of a light-emitting diode package device according to the present invention.

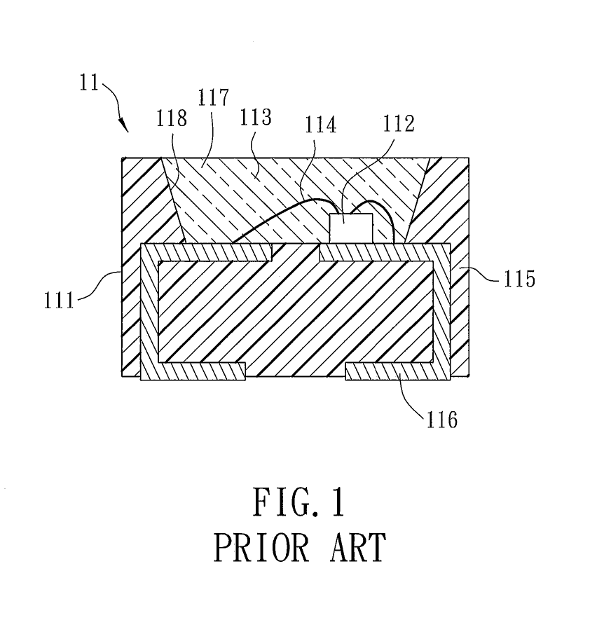

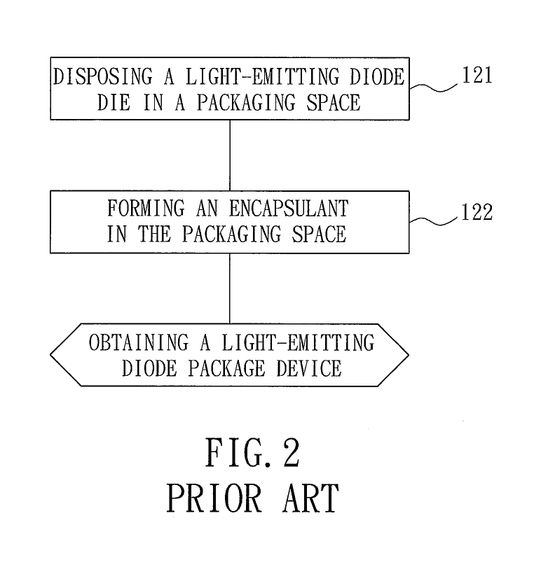

### DETAILED DESCRIPTION OF THE PREFERRED EMBODIMENTS

Before the present invention is described in greater detail, it should be noted that like components are assigned the same reference numerals throughout the following disclosure.

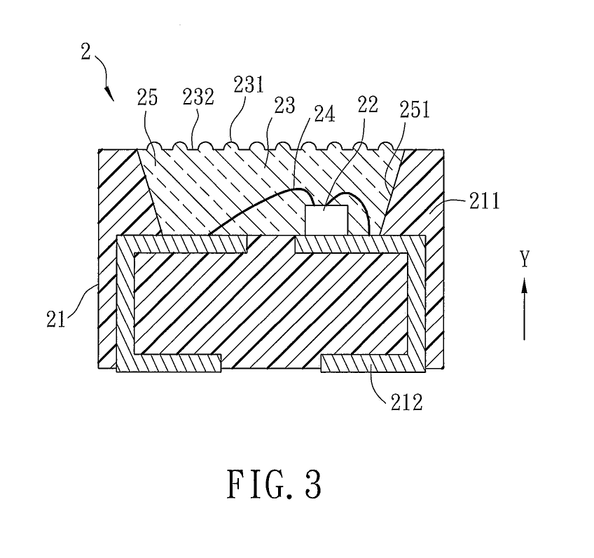

Referring to FIG. 3, the first preferred embodiment of a light-emitting diode package device 2 of the present invention comprises a base unit 21, a light-emitting diode die 22, and an encapsulant 23.

The base unit 21 has an electrically conductive lead frame 212 made mainly of a metal material and adapted for electrical connection to an external circuit (not shown), and a cup member 211 extending upwardly from a bottom portion of the lead frame 212 in a longitudinal direction (Y). The cup member 211 defines a packaging space 25 with an upper opening 251. A top portion of the lead frame 212 is exposed to a bottom of the packaging space 25.

The light-emitting diode die 22 is disposed inside the packaging space 25 to electrically connect to the exposed top portion of the lead frame 212 of the base unit 21, and is capable of emitting light when electricity is supplied thereto. In the first preferred embodiment, the light-emitting diode die 22 may convert electricity into light having a wavelength ranging from 350 to 480 nm. In the first preferred embodiment, the light-emitting diode die 22 is electrically connected to the lead frame 212 through gold wires 24. However, the electrical connection between the light-emitting diode die 22 and the lead frame 212 should not be limited to use of the gold wires 24, and any suitable means could be applied to achieve electrical connection.

The encapsulant 23 is filled in the packaging space 25 to encapsulate the light-emitting diode die 22 on the lead frame 212 and close the upper opening 251 so that the light-emitting diode die 22 is isolated from external environment. The encapsulant 23 includes an upper surface 232 spaced apart from the bottom of the packaging space 25 and to be exposed to the external environment, and a plurality of microstructures 231 formed on the upper surface 232. Each of the microstructures 231 protrudes outwardly from the upper surface 232 of the encapsulant 23 oppositely of the light-emitting diode die 22. In this embodiment, each of the microstructures 231 has a semi-circular cross section in the longitudinal direction (Y).

Preferably, the microstructures 231 are spaced apart from one another by a distance smaller than 20 microns. The microstructures 231 thus have a higher density, thereby producing an improved light refracting effect. Preferably, each of the microstructures 231 has a height from the upper surface 232. The height is greater than a wavelength of the light emitted from the light-emitting diode die 22. In this case, the light may transmit through the microstructures 231 while achieving an improved light refracting effect.

Preferably, the height of each of the microstructures 231 is smaller than 20 microns so as to enable an easy design and connection with the base unit in the manufacturing processes.

When electricity is applied from the base unit 21 to the light-emitting diode die 22, light is generated in the light-emitting diode die 22 by virtue of photoelectrical effect and transmits through the encapsulant 23 and emits outwardly.

When light emits outwardly from the light-emitting diode die 22, the microstructures 231 that are formed on the upper surface 232 of the encapsulant 23 provide a variety of refraction angles for the light. By virtue of refraction at different angles, the light emitting from the light-emitting diode package device 2 may be softer and more uniform.

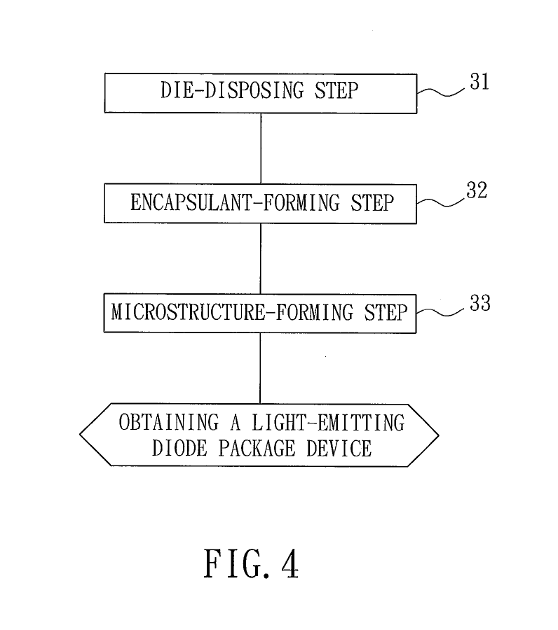

Referring to FIG. 4, a method for making the first preferred embodiment of the light-emitting diode package device 2 comprises a die-disposing step 31, an encapsulant-forming step 32, and a microstructure-forming step 33.

In the die-disposing step 31, the base unit 21 that has the electrically conductive lead frame 212 and the cup member 211 extending upwardly from the lead frame 212 is prepared. The cup member 211 defines the packaging space 25 that exposes the top portion of the lead frame 212. The light-emitting diode die 22 is disposed inside the packaging space 25 and is electrically connected to the lead frame 212 by the gold wires 24 such that the light-emitting diode die 22 can be electrically connected to the external circuit and receive external electrical power though the lead frame 212 and the gold wires 24.

Next, in the encapsulant-forming step 32, the encapsulant 23 is formed by filling an encapsulating material in the packaging space 25 and curing the encapsulating material so as to encapsulate the light-emitting diode die 22 in the packaging space 25 and isolate the light-emitting diode die 22 from the external environment.

Finally, in the microstructure-forming step 33, a plurality of microstructures 231 are formed on the upper surface 232 of the encapsulant 23 and are exposed to the external environment. In this step, a mask having a pattern corresponding to the structure of the microstructures and a lithography process are employed. Alternatively, the microstructures 231 may be formed using molding and stamping processes. Since the lithography, molding, and stamping processes are well known to one of ordinary skill in the art, detailed descriptions thereof are omitted herein for the sake of brevity.

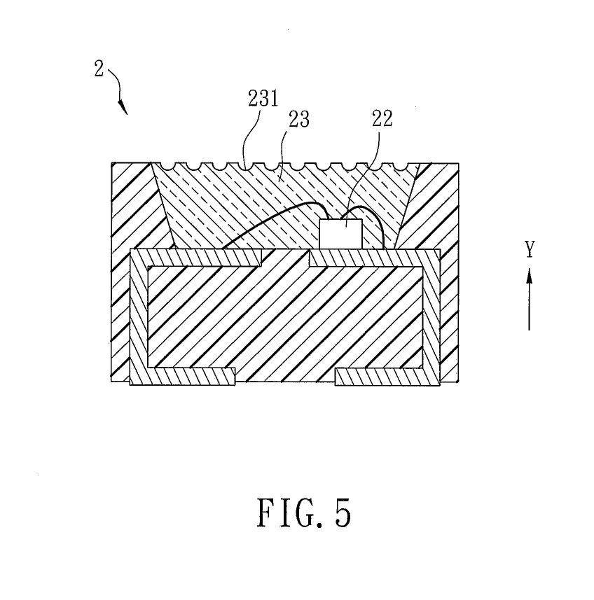

Referring to FIG. 5, the second preferred embodiment of a light-emitting diode package device 2 of this invention is shown. In this embodiment, the light-emitting diode package device 2 is similar to that of the first preferred embodiment except that each of the microstructures 231 is an indentation hole defined by a wall having a semi-circular shape in the longitudinal direction (Y) and is indented from the upper surface 232 of the encapsulant 23 toward the light-emitting diode die 22. The microstructures 231 are also spaced apart from one another by a distance smaller than 20 microns. In addition, each of the microstructures 231 has a depth from the upper surface 232. The depth is greater than a wavelength of the light emitted from the light-emitting diode die 22 and is smaller than 20 microns. In this manner, the light may be refracted at multiple angles to provide a more uniform light emission.

It is noted that, aside from the semi-circular shape, the cross section of the microstructures 231 of the first and second preferred embodiments may be any other suitable shapes, such as a semi-oval shape, a semi-elliptical shape, a twin-peak shape, or combinations thereof.

It is also noted that, in the first and second preferred embodiments, the encapsulating material may have fluorescent powders dispersed therein. The fluorescent powders may be excited by the light emitting from the light-emitting diode die 22 for emitting light having a wavelength that is different from the light emitted by the light-emitting diode die 22. For example, the fluorescent powders may be excited by the light that has a wavelength ranging from 350 to 480 nm and that emits from the light-emitting diode die 22 to emit light having a wavelength ranging from 480 to 700 nm. In this manner, the light-emitting diode package device 2 may emit mixed light having a wavelength ranging from 350 to 700 nm.

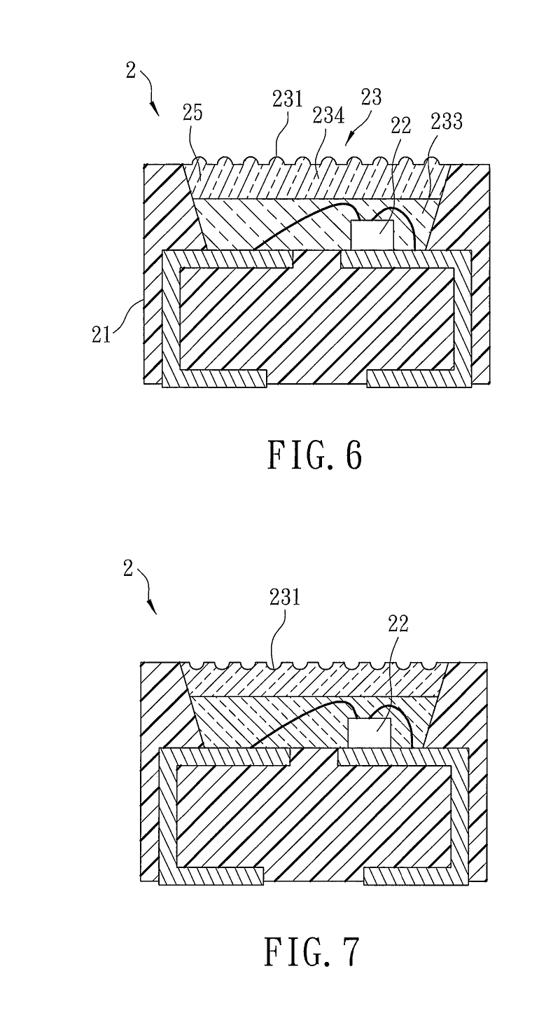

Referring to FIG. 6, the third preferred embodiment of a light-emitting diode package device 2 of this invention is shown. In this embodiment, the light-emitting diode package device 2 is similar to that of the first preferred embodiment except that the encapsulant 23 includes a transparent layer 233 and a fluorescent layer 234 dispersed with fluorescent powders. The transparent layer 233 is disposed adjacent to the bottom of the packaging space 25 of the base unit 21 while the fluorescent layer 234 is formed on the transparent layer 233 oppositely of the base unit 21. The microstructures 231 are formed on the fluorescent layer 234. In addition, the transparent layer 233 is made of a transparent material and encapsulates and isolates the light-emitting diode die 22 from the external environment.

When electrical power is supplied to the light-emitting diode package device 2 of the third preferred embodiment, the light-emitting diode die 22 may convert electrical power to light that in turn passes through the transparent layer 233 and then the fluorescent layer 234 to the external environment. The light transmitted through the fluorescent layer 234 may be excited by the fluorescent powders to emit mixed light. Since the fluorescent powders of the fluorescent layer 234 are spaced apart from the light-emitting diode die 22, precipitation of the fluorescent powders on the light-emitting diode die 22 can be avoided.

A method for making the light-emitting diode package device 2 of the third preferred embodiment is similar to the method for making the light-emitting diode package device 2 of the first preferred embodiment except that the encapsulant-forming step 32 includes filling a transparent encapsulating material into the packaging space 25; filling another transparent encapsulating material (not shown) dispersed with fluorescent powders in the packaging space 25; and curing the transparent encapsulating materials so as to form the transparent layer 233 and the fluorescent layer 234. Thereafter, the fluorescent layer 234 is subjected to a lithography process using a mask or molding and stamping processes so as to form the microstructures 231 on the fluorescent layer 234.

Referring to FIG. 7, the fourth preferred embodiment of a light-emitting diode package device 2 of this invention is shown. In this embodiment, the light-emitting diode package device 2 is similar to that of the third preferred embodiment except that the microstructures 231 have a structure the same as that of the microstructures 231 in the second preferred embodiment, i.e., the microstructures 231 are indented from the upper surface 232 of the encapsulant 23 toward the light-emitting diode die 22.

To sum up, with the microstructures 231 formed on the upper surface 232 of the encapsulant 23, light emitting from the light-emitting diode die 22 may be refracted at various angles, thereby gene rating a softer and more uniform light.

While the present invention has been described in connection with what are considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A light-emitting diode package device, comprising:
a base unit defining a packaging space;
a light-emitting diode die that is disposed inside said packaging space to electrically connect to said base unit and that is capable of emitting light; and
an encapsulant that is filled in said packaging space to encapsulate said light-emitting diode die and that includes an upper surface to be exposed to external environment, and a plurality of microstructures formed on said upper surface.

2. The light-emitting diode package device of claim 1, wherein each of said microstructures protrudes from said upper surface of said encapsulant oppositely of said light-emitting diode die, said microstructures being spaced apart from one another by a distance smaller than 20 microns.

3. The light-emitting diode package device of claim 2, wherein each of said microstructures has a height from said upper surface, said height being greater than a wavelength of the light emitted from said light-emitting diode die, and being smaller than 20 microns.

4. The light-emitting diode package device of claim 3, wherein said encapsulant includes a transparent layer and a fluorescent layer dispersed with fluorescent powders.

5. The light-emitting diode package device of claim 3, wherein said encapsulant is formed from a transparent encapsulating material dispersed with fluorescent powders.

6. The light-emitting diode package device of claim 1, wherein each of said microstructures is indented from said upper surface of said encapsulant toward said light-emitting diode die, and said microstructures are spaced apart from one another by a distance smaller than 20 microns.

7. The light-emitting diode package device of claim 6, wherein each of said microstructures has a depth from said upper surface, said depth being greater than a wavelength of the light emitted from said light-emitting diode die, and being smaller than 20 microns.

8. The light-emitting diode package device of claim 7, wherein said encapsulant includes a transparent layer and a fluorescent layer dispersed with fluorescent powders.

9. The light-emitting diode package device of claim 7, wherein said encapsulant is formed from a transparent encapsulating material dispersed with fluorescent powders.

10. A method for making a light-emitting diode package device, comprising:
(a) disposing a light-emitting diode die inside a packaging space defined by a base unit such that the light-emitting diode die is electrically connected to the base unit;
(b) forming an encapsulant by filling an encapsulating material in the packaging space to encapsulate the light-emitting diode die; and
(c) forming a plurality of microstructures on an upper surface of the encapsulant that is to be exposed to external environment, the microstructures being spaced apart from one another by a distance smaller than 20 microns, each of the microstructures having an end surface spaced apart from the upper surface of the encapsulant, a distance between the end surface of each of the microstructures and the upper surface of the encapsulant being greater than a wavelength of the light emitted from said light-emitting diode die, and being smaller than 20 microns.

11. The method of claim 10, wherein the microstructures are formed using a mask and a lithography process.

12. The method of claim 10, wherein the microstructures are formed using molding and stamping processes.

13. The method of claim 10, wherein step (b) includes:
(i) filling a transparent encapsulating material into the packaging space;
(ii) filling another transparent encapsulating material dispersed with fluorescent powders in the packaging space; and
(iii) curing the transparent encapsulating materials.
